(19) United States
(12) Patent Application Publication
(10) Pub. No.: US 2026/0100211 A1
(43) Pub. Date: Apr. 9, 2026

(54) Data storage device and memory controller with reduced internal signal transmission delay

(71) Applicant: Silicon Motion, Inc, Hsinchu County (TW)

(72) Inventor: Han-Cheng Huang, Taipei City (TW)

(73) Assignee: Silicon Motion, Inc, Hsinchu County (TW)

(21) Appl. No.: 19/054,922

(22) Filed: Feb. 17, 2025

Related U.S. Application Data
(60) Provisional application No. 63/705,045, filed on Oct. 9, 2024.

(30) Foreign Application Priority Data
Jan. 14, 2025 (TW) 114101509

(51) Int. Cl. G11C 8/18

(52) U.S. Cl. CPC G11C 8/18

(57) ABSTRACT

A data storage device includes a memory device and a host interface. The host interface, communicates with a host device and includes a first circuit and a second circuit. The first circuit is configured on a signal reception path and operates in a first power domain. The first circuit receives a plurality of signals from the host device, and the signals comprise a clock signal provided by the host device. The second circuit is configured on a signal transmission path and operates in the first power domain. The second circuit outputs data read from the memory device according to the clock signal. The first circuit is coupled to the second circuit and the clock signal is directly provided from the first circuit to the second circuit.

### CROSS REFERENCE TO RELATED APPLICATIONS

This application claims the benefit of U.S. Provisional Application No. 63/705,045, filed on October 9, 2024. The content of the application is incorporated herein by reference.

### BACKGROUND OF THE INVENTION

### 1. Field of the Invention

The present invention is related to a data storage device with reduced internal signal transmission delay.

### 2. Description of the Prior Art

With the rapid growth of data storage technology in recent years, many data storage devices—such as memory cards manufactured in compliance with the Secure Digital (SD)/ Multi Media Card (MMC) standards, Compact Flash (CF) standards, Memory Stick (MS) standards or Extreme Digital (XD) standards, as well as Solid State Disk (SSD) drives, Embedded Multi Media Cards (eMMC) and Universal Flash Storage (UFS)—have been used widely for a variety of purposes. In addition, the data rate of the data storage devices keeps increasing with the advance of data storage technology as well.

However, as the data rate increases, the margin to correctly latch or sample data decreases, causing the error rate of latching or sampling data to possibly increase in certain conditions. Therefore, improving performance of the data storage devices is an important issue in the field of data storage.

### SUMMARY OF THE INVENTION

According to an embodiment of the invention, a data storage device comprises a memory device and a host interface. The host interface communicates with a host device and comprises a first circuit and a second circuit. The first circuit is on a signal reception path and operates in a first power domain. The first circuit receives a plurality of signals from the host device, and the plurality of signals comprise a clock signal provided by the host device. The second circuit is on a signal transmission path and operates in the first power domain. The second circuit outputs data read from the memory device according to the clock signal. The first circuit is coupled to the second circuit and the clock signal is directly provided from the first circuit to the second circuit.

According to an embodiment of the invention, a memory controller is coupled to a memory device and a host device and comprises a host interface communicating with the host device. The host interface comprises a first circuit and a second circuit. The first circuit is on a signal reception path and operates in a first power domain. The first circuit receives a plurality of signals from the host device, and the plurality of signals comprise a clock signal provided by the host device. The second circuit is on a signal transmission path and operates in the first power domain. The second circuit outputs data read from the memory device according to the clock signal. The first circuit is coupled to the second circuit and the clock signal is directly provided from the first circuit to the second circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows an exemplary block diagram of a data storage device according to an embodiment of the invention.

FIG. 2 shows an exemplary signal transmission path of the data storage device.

FIG. 3 shows an exemplary circuit diagram of a portion of circuits in the host interface according to an embodiment of the invention.

### DETAILED DESCRIPTION

In the following, numerous specific details are described to provide a thorough understanding of embodiments of the invention. However, one of skilled in the art will understand how to implement the invention in the absence of one or more specific details, or relying on other methods, elements or materials. In other instances, well-known structures, materials or operations are not shown or described in detail in order to avoid obscuring the main concepts of the invention.

Reference throughout this specification to “one embodiment”, “an embodiment”, “one example” or “an example” means that a particular feature, structure or characteristic described in connection with the embodiment or example is included in at least one embodiment of a plurality of embodiments. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or sub-combinations in one or more embodiments or examples.

In addition, in order to make the objects, features and advantages of the invention more comprehensible, specific embodiments of the invention are set forth in the accompanying drawings. This description is made for the purpose of illustrating the general principles of the invention and should not be taken in a limiting sense. It should be understood that the following embodiments can be implemented by software, hardware, firmware, or any combination thereof.

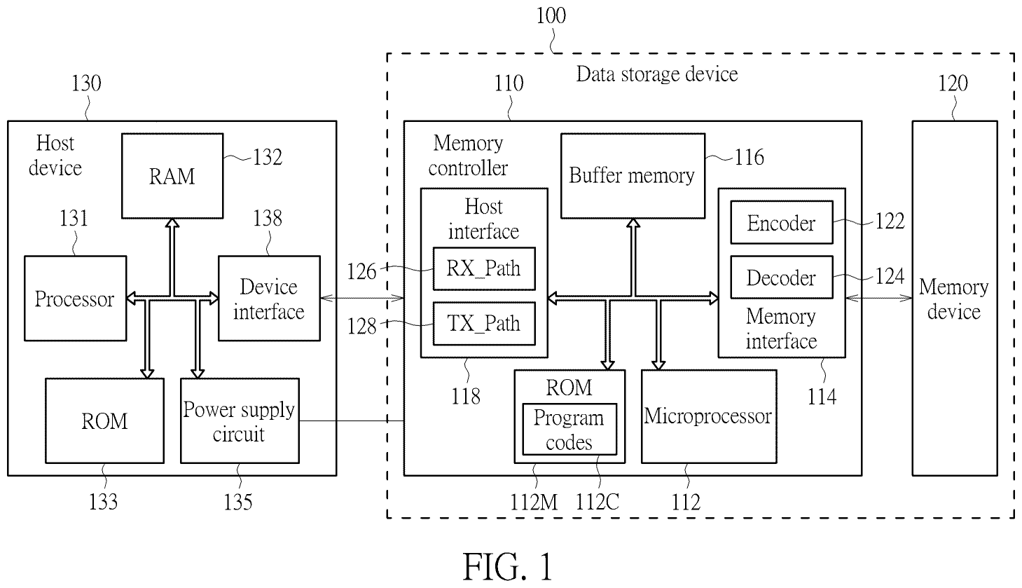

FIG. 1 shows an exemplary block diagram of a data storage device according to an embodiment of the invention. The data storage device 100 may comprise a memory device 120 and a memory controller 110. The memory controller 110 is configured to access the memory device 120 and control operations of the memory device 120. The memory device 120 may be a non-volatile (NV) memory (e.g., a Flash memory) device and may comprise one or more memory elements (e.g., one or more Flash memory dies, or one or more Flash memory chip, or the likes).

The data storage device 100 may be coupled to a host device 130. The host device 130 may comprise at least one processor 131, at least one random access memory (RAM) 132, such as at least one dynamic RAM (DRAM), at least one static RAM (SRAM), etc., at least one read only memory (ROM) 133, a power supply circuit 135 and a device interface 138.

The host device 130 may access the data storage device 100 through the device interface 138. The processor 131, the device interface 138, the RAM 132 and the ROM 133 may be coupled to each other through a bus, and may be coupled to the power supply circuit 135 to obtain power. The processor 131 may be arranged to control operations of the host device 130. The ROM 133 is configured to store program codes. The processor 131 may be configured to execute the program codes, thereby controlling operations of the host device 130.

The power supply circuit 135 may be arranged to provide the processor 131, the device interface 138, the RAM 132 and ROM 133 with power as well as provide the data storage device 100 with power through the bus or the power lines. For example, the power supply circuit 135 may output one or more driving voltages to the data storage device 100. The data storage device 100 may obtain the one or more driving voltages from the host device 130 as the power of the data storage device 100 and provide the host device 130 with storage space.

According to an embodiment of the invention, the memory controller 110 may comprise a microprocessor 112, a ROM 112M, a memory interface 114, a buffer memory 116 and a host interface 118. The ROM 112M is configured to store program codes 112C. The microprocessor 112 is configured to execute the program codes 112C, thereby controlling access to the memory device 120. The program codes 112C may comprise one or more program modules, such as the boot loader code. When the data storage device 100 obtains power from the host device 130, the microprocessor 112 may perform an initialization procedure of the data storage device 100 by executing the program codes 112C. In the initialization procedure, the microprocessor 112 may load a group of In-System Programming (ISP) codes (not shown in FIG. 1) from the memory device 120. The microprocessor 112 may execute the group of ISP codes, so that the data storage device 100 has various functions. According to an embodiment of the invention, the group of ISP codes may comprise, but are not limited to: one or more program modules related to memory access (e.g., read, write and erase), such as a read operation module, a table lookup module, a wear leveling module, a read refresh module, a read reclaim module, a garbage collection module, a sudden power off recovery (SPOR) module and an uncorrectable error correction code (UECC) module, respectively provided for performing the operations of read, table lookup, wear leveling, read refresh, read reclaim, garbage collection, SPOR and error handling for detected UECC error.

The memory interface 114 may comprise an encoder 122 and a decoder 124. The encoder 122 is configured to encode the data to be written into the memory device 120, such as performing ECC encoding. The decoder 124 is configured decode the data read out from the memory device 120.

Typically, the memory device 120 may comprise a plurality of memory elements, such as a plurality of Flash memory dies or Flash memory chips, and each memory element may comprise a plurality of memory blocks. The access unit of an erase operation performed by the memory controller 110 on the memory device 120 may be one memory block. In addition, a memory block may record (comprise) a predetermined number of pages, for example, the physical pages, and the access unit of a write operation or a read operation performed by the memory controller 110 on the memory device 120 may be one page.

In practice, the memory controller 110 may perform various control operations by using its own internal components. For example, the memory controller 110 may use the memory interface 114 to control the access operations (especially the access operation for at least a memory block or at least a page) of the memory device 120, use the buffer memory 116 to perform necessary data buffer operations, and use the host interface 118 to communicate with the host device 130. The host interface 118 may comprise at least a signal reception path RX_Path 126 and a signal transmission path TX_Path 128 for processing the data and signals received from and to be transmitted to the host device 130.

In an embodiment of the invention, the memory controller 110 may use the host interface 118 to communicate with the host device 130 in compliance with a standard communication protocol. For example, the standard communication protocol may comprise (but is not limited to) the Universal Serial Bus (USB) standard, the SD interface standard, the Ultra High Speed-I (UHS-I) interface standard, the Ultra High Speed-II (UHS-II) interface standard, the CF interface standard, the MMC interface standard, the eMMC interface standard, the UFS interface standard, the Advanced Technology Attachment (ATA) standard, the Serial ATA (SATA) standard, the Peripheral Component Interconnect Express (PCI-E) standard, the Parallel Advanced Technology Attachment (PATA) standard, etc.

In an embodiment, the buffer memory 116 may be implemented by a RAM. For example, the buffer memory 116 may be an SRAM, but the invention should not be limited thereto. In other embodiments, the buffer memory 116 may be a DRAM.

In an embodiment of the invention, the data storage device 100 may be a portable storage device (for example, the memory card in compliance with the SD/MMC, CF, MS and/or XD standard), and the host device 130 may be an electronic device, such as a mobile phone, a notebook computer, a desktop computer...etc., capable of connecting to the data storage device. In another embodiment of the invention, the data storage device 100 may be a solid state hard disk or an embedded storage device in compliance with the UFS or the eMMC standards, and may be equipped in an electronic device such as a mobile phone, a notebook computer, or a desktop computer. In such an embodiment, the host device 130 may be a processor of the electronic device.

The host device 130 may issue commands, such as the read command or the write command, to the data storage device 100, so as to access the data stored in the memory device 120, or the host device 130 may issue commands to further control or manage the data storage device 100.

The data storage device 100 may operate based on a clock signal CLK. In some embodiments of the invention, the clock signal CLK may be provided by the host device 130, for example, the data storage device 100 may receive the clock signal CLK from the host device 130, and the transmission of the clock signal may be unidirectional. In a write operation, the data storage device 100 may receive the clock signal CLK from the host device 130 and receive data that the host device 130 intends to write or store in the memory device 120 according to the clock signal CLK. In a read operation, the data storage device 100 may receive the clock signal CLK from the host device 130 and output the data read from the memory device 120 according to the clock signal CLK.

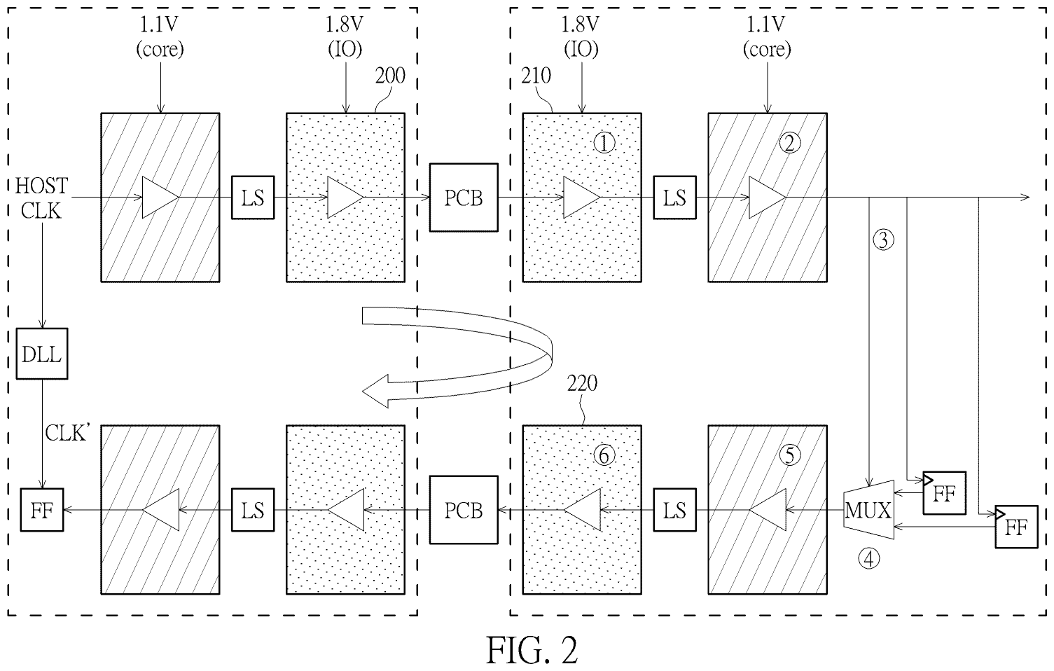

FIG. 2 shows an exemplary signal transmission path of the data storage device, for illustrating the internal signal transmission delay of the data storage device. The clock signal CLK provided by the host device (labeled as ‘HOST CLK’) travels from an output pad in circuit 200 of the host device through the Printed Circuit Board (PCB) to an input pad in circuit 210 of the data storage device. The circuit 200 may be comprised in the device interface of the host device. The circuit 210 may be comprised in the host interface of the data storage device. The host interface may comprise an input-output (IO) portion and a core portion. The IO portion may act as a bridge for external communication of the core portion. The circuits in the IO portion may operate in a first power domain (for example, 0˜1.8V) and the circuits in the core portion may operate in a second power domain (for example, 0˜1.1V). The circuit 210 receiving the clock signal CLK may be configured in the IO portion of the host interface.

As the power domains are different, the clock signal CLK may be voltage level shifted (for example, shifted from the voltage level belonging to the first power domain to the voltage level belonging to the second power domain) by a level shifter LS before being provided to the core portion. The voltage level shifted clock signal CLK may be then transmitted to subsequent circuits in the core portion for further processing.

As described above, since the data read from the memory device 120 in a read operation is output based on the clock signal CLK received from the host device, the clock signal CLK will be provided to a multiplexer (MUX) for outputting data. As shown in FIG. 2, the multiplexer is coupled to two flip-flops (FF). The multiplexer may selectively output the data received from respective FF based on the clock signal CLK. The data output by the multiplexer may be provided to an output buffer in the core portion, level shifted by a level shifter LS, and then provided to an output pad in circuit 220 in the IO portion. The data may be output by the output pad in the circuit 220 and transmitted to the host device through the PCB.

In the exemplary signal transmission path shown in FIG. 2, there are at least 6 cell delays generated inside the data storage device, including the first cell delay (labeled by the number ‘1’) generated in the input pad in the circuit 210, the second cell delay (labeled by the number ‘2’) generated when being input to the core power domain (for example, generated in a buffer), the third cell delay (labeled by the number ‘3’) generated in the clock tree for transmitting the clock signal CLK, the fourth cell delay (labeled by the number ‘4’) generated in the multiplexer, the fifth cell delay (labeled by the number ‘5’) generated when being output from the core power domain (for example, generated in a buffer) and the sixth cell delay (labeled by the number ‘6’) generated in the output pad in the circuit 220.

There are many factors that may affect the length of the cell delay. Among them, a key factor may be the temperature. When the temperature increases, the cell delay increases as well. Therefore, for the transmission of the clock signal CLK inside the data storage device 100, the cell delay may contribute internal signal transmission delay and may cause undesired phase delay to the clock signal CLK.

The phase delay may affect the correctness of latching or sampling data (hereinafter using the term ‘sampling’ (as well as ‘sample’ or ‘sampled’) for brevity). For example, in the read operation, the host device 130 may sample the data received from the data storage device 100 according to a reference clock signal CLK′ reproduced by itself. The reference clock signal CLK′ reproduced by the host device 130 may be a replica of the clock signal CLK provided by the host device 130 and utilized by the data storage device 100 for outputting the data. For example, the reference clock signal CLK′ may be generated by a Delay Locked Loop (DLL) circuit, and the clock signal CLK and reference clock signal CLK′ have the same frequency.

However, as the phase delay of the clock signal CLK increases, the phase previously estimated and utilized for reproducing the reference clock signal CLK′ may become unaligned with the phase of the clock signal CLK, thereby decreasing the margin to correctly sample data and increasing the error rate of sampling data at the host device 130. For example, when the phase different between the clock signal CLK and the reference clock signal CLK′ exceeds the margin (e.g., a time margin or a phase margin) of the clock signal to correctly sample data, an erroneous sampling result may be obtained.

The data error rate may be further increased when the data rate (data transmission rate) between the data storage device 100 and the host device 130 increases, due to the reason that the margin to correctly sample data decreases. To avoid obtaining erroneous sampling result at the host device due to undesired phase delay, a novel circuit structure is proposed to reduce internal signal transmission delay in the data storage device.

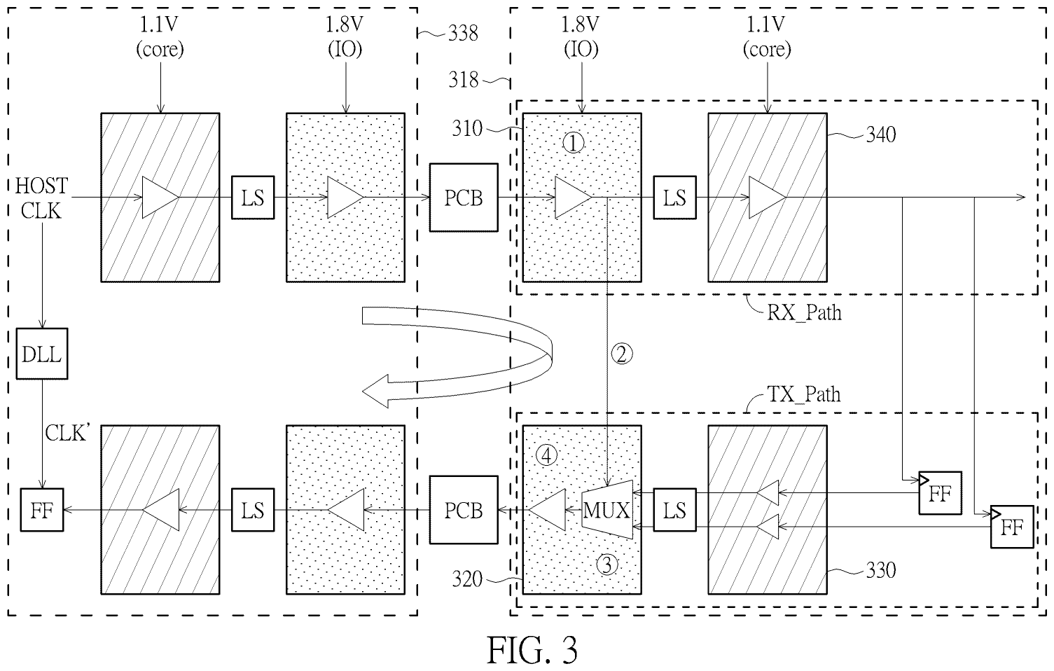

FIG. 3 shows an exemplary circuit diagram of a portion of circuits in the host interface according to an embodiment of the invention. In the embodiments of the invention, the host interface 318 may comprise a signal reception path RX_Path and a signal transmission path TX_Path. The signal reception path RX_Path and the signal transmission path TX_Path may respectively comprise one or more signal processing circuits to perform necessary signal processing.

For example, the host interface 318 may comprise a first circuit 310 on the RX_Path. According to an embodiment of the invention, the first circuit 310 may operate in a first power domain (for example, 0˜1.8V) and receive a plurality of signals from the host device (e.g., from the device interface 338 of the host device), where the signals may comprise a clock signal (e.g., the clock signal CLK) provided by the host device (labeled as ‘HOST CLK’). The host interface 318 may further comprise a second circuit 320 on the TX_Path. According to an embodiment of the invention, the second circuit 320 may operate in the first power domain and output data read from the memory device (e.g., the memory device 120) according to the clock signal.

The host interface 318 may further comprise a level shifter LS and a third circuit 330 on the TX_Path. The third circuit 330 may operate in a second power domain (for example, 0˜1.1V) and output the signals or data read from the memory device 120 to the second circuit 320. The level shifter LS may be coupled between the second circuit 320 and the third circuit 330 and shift a voltage level of the signals or data from the second power domain to the first power domain (for example, shift the voltage level from the voltage level belonging to the second power domain to the voltage level belonging to the first power domain). Similarly, the host interface 318 may further comprise a level shifter LS and a fourth circuit 340 on the RX_Path. The fourth circuit 340 may operate in the second power domain (for example, 0˜1.1V) and receive the signals or data from the first circuit 310. The level shifter LS may be coupled between the first circuit 310 and the fourth circuit 340 and shift a voltage level of the signals or data from the first power domain to the second power domain (for example, shift the voltage level from the voltage level belonging to the first power domain to the voltage level belonging to the second power domain).

According to an embodiment of the invention, the first circuit 310 and the second circuit 320 may be comprised in the IO portion of the host interface 318 and the third circuit 330 and the fourth circuit 340 may be comprised in the core portion of the host interface 318. According to an embodiment of the invention, the first circuit 310 may be comprised in or may be a first IO pad (such as an input pad) on the RX_Path, the second circuit 320 may be comprised in or may be a second IO pad (such as an output pad) on the TX_Path.

According to an embodiment of the invention, the first power domain may be an IO power domain and may be powered by a first power supply voltage (e.g., 1.8V), the second power domain may be a core power domain and may be powered by a second power supply voltage (e.g., 1.1V), and the first power supply voltage may be higher than the second power supply voltage.

Note that the 1.8V and 1.1V voltages recited here and depicted in the figures are merely exemplary values to illustrate the operating voltage difference between the IO portion and the core portion of the host interface circuit, and are not intended to limit the scope of the invention. One of skilled in the art will understand that the operating voltage of the devices and/or circuits configured in the IO portion may be different from that of the devices and/or circuits configured in the core portion, and the operating voltages thereof may be different by different processes and may also vary with the processes advance.

According to an embodiment of the invention, the first circuit 310 may be coupled to the second circuit 320 and the clock signal CLK may be directly provided from the first circuit 310 to the second circuit 320, to reduce internal signal transmission delay of the clock signal CLK.

According to an embodiment of the invention, the clock signal CLK provided from the first circuit 310 to the second circuit 320 does not go into the core power domain.

According to an embodiment of the invention, the clock signal CLK provided from the first circuit 310 to the second circuit 320 does not undergo a voltage level shifting operation by the level shifter LS on the RX_Path and a voltage level shifting operation by the level shifter LS on the TX_Path.

According to an embodiment of the invention, the first circuit 310 may comprise a buffer for driving and outputting the signals received from the host device 130. In addition, the second circuit 320 may comprise a multiplexer (MUX). The multiplexer may comprise a first data input terminal, a second data input terminal and a clock input terminal. The first data input terminal may be coupled to a first FF to receive a first portion of the data read from the memory device 120. The second data input terminal may be coupled to a second FF to receive a second portion of the data read from the memory device 120. The clock input terminal may receive the clock signal CLK from the first circuit 310. According to an embodiment of the invention, the multiplexer MUX may multiplex the first portion of the data and the second portion of the data into an output data stream according to the clock signal CLK.

According to an embodiment of the invention, an output terminal of the buffer in the first circuit 310 may be coupled to the clock input terminal of the multiplexer in the second circuit 320, such as the connection between the output of the buffer and the multiplexer shown in FIG. 3, to directly provide the clock signal CLK from the first circuit 310 to the second circuit 320 in the IO power domain.

According to an embodiment of the invention, a clock pin on the RX_Path of the host interface 318 for receiving the clock signal CLK from host device 130 may be coupled to the IO pad (such as an output pad) on the TX_Path of the host interface 318 for outputting data to the host device 130, to directly provide the clock signal CLK from the RX_Path to the TX_Path in the IO power domain.

According to an embodiment of the invention, the clock signal CLK provided to the multiplexer or the IO pad on the TX_Path of the host interface 318 for outputting data to the host device 130 does not go into the core portion of the host interface 318 as the other signals received from the host device 130. Therefore, the clock signal CLK does not undergo a voltage level shifting operation by the level shifter LS as the other signals received from the host device 130 and to be provided to the subsequent circuits in the core portion for further processing.

Since the clock signal CLK does not go into the core portion of the host interface 318, the internal signal transmission delay of the clock signal CLK is effectively reduced.

For the exemplary signal transmission path in the circuit structure shown in FIG. 3, there are 4 cell delays generated inside the data storage device 100, including the first cell delay (labeled by the number ‘1’) generated in the first circuit 310, the second cell delay (labeled by the number ‘2’) generated in the clock tree for transmitting the clock signal CLK, the third cell delay (labeled by the number ‘3’) generated in the multiplexer in the second circuit 320 and the fourth cell delay (labeled by the number ‘4’) generated in the buffer in the second circuit 320. As compared to the signal transmission path shown in FIG. 2, since the amount of cell delays is reduced, the signal transmission delay of the clock signal CLK is effectively reduced.

In addition, in the circuit structure shown in FIG. 3, the signal transmission path (i.e., the delay path) of the clock signal CLK is only related to the IO power domain, and is unrelated, isolated or independent from the core power domain. Therefore, the power and phase delay of the clock signal CLK will not vary with the core power drift (i.e., will not be affected by the core power drift). For example, the core power may vary with the loading of the circuit or module in the core portion, and core power drift may occur when the loading is heavy. The core power drift may affect the path delay of the signals transmitted in the core portion. In the embodiments of the invention, since the clock signal CLK utilized for outputting the data read from the memory device is not transmitted in the core power domain, the path delay, as well as the phase delay, of the clock signal CLK will no longer be affected by the core power drift.

In the embodiments of the invention, the proposed circuit structure in the host interface effectively reduces the signal transmission delay of the clock signal CLK, thereby reducing (as well as limiting) the phase delay of the clock signal CLK as compared to the signal transmission path shown in FIG. 2. In addition, since the clock signal CLK is not transmitted in the core power domain, the phase delay of the clock signal CLK will no longer be affected by the core power drift, thereby further stabilizing the phase delay of the clock signal CLK as compared to the case when the clock signal CLK is provided from the core power domain to the IO power domain. As the phase delay of the clock signal CLK is reduced and stabilized in the proposed circuit structure, the phase different between the clock signal CLK and the reference clock signal CLK′ reproduced by the host device 130 can be limited and kept as not exceeding the margin to correctly sample data, thereby the data can be correctly sampled by the host device 130.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A data storage device, comprising:
a memory device; and
a host interface, communicating with a host device, wherein the host interface comprises:
a first circuit, on a signal reception path and operating in a first power domain, wherein the first circuit receives a plurality of signals from the host device, and wherein the plurality of signals comprise a clock signal provided by the host device; and
a second circuit, on a signal transmission path and operating in the first power domain, wherein the second circuit outputs data read from the memory device according to the clock signal, and
wherein the first circuit is coupled to the second circuit and the clock signal is directly provided from the first circuit to the second circuit.

2. The data storage device of claim 1, wherein the host interface further comprises:
a third circuit, on the signal transmission path, wherein the third circuit operates in a second power domain and outputs the data to the second circuit; and
a level shifter, coupled between the second circuit and the third circuit, wherein the level shifter performs a voltage level shifting operation to shift a voltage level of the data from the second power domain to the first power domain.

3. The data storage device of claim 2, wherein the first power domain is powered by a first power supply voltage, the second power domain is powered by a second power supply voltage, and the first power supply voltage is higher than the second power supply voltage.

4. The data storage device of claim 2, wherein the first circuit and the second circuit are comprised in an input-output (IO) portion of the host interface and the third circuit is comprised in a core portion of the host interface.

5. The data storage device of claim 2, wherein the clock signal provided from the first circuit to the second circuit does not go into the second power domain.

6. The data storage device of claim 2, wherein the clock signal provided from the first circuit to the second circuit does not undergo the voltage level shifting operation by the level shifter.

7. The data storage device of claim 1, wherein the first circuit comprises:
a buffer, driving and outputting the plurality of signals, and
wherein the second circuit comprises:
a multiplexer, comprising:
a first data input terminal, receiving a first portion of the data;
a second data input terminal, receiving a second portion of the data; and
a clock input terminal, receiving the clock signal,
wherein the multiplexer multiplexes the first portion of the data and the second portion of the data into an output data stream according to the clock signal.

8. The data storage device of claim 7, wherein an output terminal of the buffer is coupled to the clock input terminal of the multiplexer.

9. The data storage device of claim 1, wherein the first circuit is comprised in a first IO pad on the signal reception path and the second circuit is comprised in a second IO pad on the signal transmission path.

10. A memory controller, coupled to a memory device and a host device and comprising:
a host interface, communicating with the host device and comprising:
a first circuit, on a signal reception path and operating in a first power domain, wherein the first circuit receives a plurality of signals from the host device, and wherein the plurality of signals comprise a clock signal provided by the host device; and
a second circuit, on a signal transmission path and operating in the first power domain, wherein the second circuit outputs data read from the memory device according to the clock signal, and
wherein the first circuit is coupled to the second circuit and the clock signal is directly provided from the first circuit to the second circuit.

11. The memory controller of claim 10, wherein the host interface further comprises:
a third circuit, on the signal transmission path, wherein the third circuit operates in a second power domain and outputs the data to the second circuit; and
a level shifter, coupled between the second circuit and the third circuit, wherein the level shifter performs a voltage level shifting operation to shift a voltage level of the data from the second power domain to the first power domain.

12. The memory controller of claim 11, wherein the first power domain is powered by a first power supply voltage, the second power domain is powered by a second power supply voltage, and the first power supply voltage is higher than the second power supply voltage.

13. The memory controller of claim 11, wherein the first circuit and the second circuit are comprised in an input-output (IO) portion of the host interface and the third circuit is comprised in a core portion of the host interface.

14. The memory controller of claim 11, wherein the clock signal provided from the first circuit to the second circuit does not go into the second power domain.

15. The memory controller of claim 11, wherein the clock signal provided from the first circuit to the second circuit does not undergo the voltage level shifting operation by the level shifter.

16. The memory controller of claim 10, wherein the first circuit comprises:
a buffer, driving and outputting the plurality of signals, and
wherein the second circuit comprises:
a multiplexer, comprising:
a first data input terminal, receiving a first portion of the data;
a second data input terminal, receiving a second portion of the data; and
a clock input terminal, receiving the clock signal,
wherein the multiplexer multiplexes the first portion of the data and the second portion of the data into an output data stream according to the clock signal.

17. The memory controller of claim 16, wherein an output terminal of the buffer is coupled to the clock input terminal of the multiplexer.

18. The memory controller of claim 10, wherein the first circuit is comprised in a first IO pad on the signal reception path and the second circuit is comprised in a second IO pad on the signal transmission path.
